(19) United States
(12) Patent Application Publication
(10) Pub. No.: US 2025/0131169 A1
(43) Pub. Date: Apr. 24, 2025

(54) MACHINE-LEARNING APPARATUS, PUMP-PERFORMANCE PREDICTION APPARATUS, INFERENCE APPARATUS, PUMP-SHAPE DESIGNING APPARATUS, MACHINE-LEARNING METHOD, PUMP-PERFORMANCE PREDICTION METHOD, INFERENCE METHOD, PUMP-SHAPE DESIGNING METHOD, MACHINE LEARNING PROGRAM, PUMP-PERFORMANCE PREDICTION PROGRAM, INFERENCE PROGRAM, AND PUMP-SHAPE DESIGNING PROGRAM

(71) Applicant: EBARA CORPORATION, Tokyo (JP)

(72) Inventors: Szu Yung CHEN, Tokyo (JP); Akira GOTO, Tokyo (JP); Hiroyoshi WATANABE, Tokyo (JP); Lingjia ZHAO, Tokyo (JP); Hidenobu OKAMOTO, Tokyo (JP); Mehrdad ZANGENEH, London (GB)

(21) Appl. No.: 18/689,104

(22) PCT Filed: Sep. 7, 2022
(86) PCT No.: PCT/JP2022/033533

§ 371 Date: Mar. 5, 2024

(30) Foreign Application Priority Data
Sep. 9, 2021 (JP) 2021-147056

(51) Int. Cl. G06F 30/28; G06F 30/27

(52) U.S. Cl. CPC G06F 30/28; G06F 30/27

(57) ABSTRACT

A machine-learning apparatus includes: a learning-data storage section that stores plural sets of learning data including input data and output data, the input data including shape parameters of a pump section having an impeller and a flow passage section in which the impeller is accommodated, the output data including pump performance of a pump having the pump section defined by the shape parameters; a machine-learning section configured to cause a learning model to learn a correlation between the input data and the output data by inputting the plural sets of the learning data to the learning model; and a learned-model storage section configured to store the learning model that has been caused to learn the correlation by the machine-learning section.

### TECHNICAL FIELD

The present invention relates to a machine-learning apparatus, a pump-performance prediction apparatus, an inference apparatus, a pump-shape designing apparatus, a machine-learning method, a pump-performance prediction method, an inference method, a pump-shape designing method, a machine learning program, a pump-performance prediction program, an inference program, and a pump-shape designing program.

### BACKGROUND ART

“Specific speed Ns” is a parameter that characterizes flow of fluid in a pump and is the most important similarity law that governs performance characteristics of the pump. Therefore, types and performance characteristics of various pumps are organized based on the specific speed Ns. A series development method based on the specific speed Ns is adopted in a pump design process. The specific speed Ns is calculated by the following formula,

Ns=N·Q^{1/2}/H^{3/4}[min⁻¹,m³/min,m]

where [min⁻¹], [m³/min], and [m] are units for rotational speed N, flow rate Q, and head H, respectively.

For example, a baseline pump having a specific speed close to the specific speed Ns satisfying target required specifications (flow rate, head, etc.) is selected, and a shape of an impeller of that pump is then adjusted (or trimmed), so that the pump performance is optimized. Patent Document 1 describes a pump design method in which CFD analysis or experiment is performed on an impeller formed in a predetermined shape, which is adjusted if the pump performance does not reach a desired performance. Patent Document 2 describes a method of designing a centrifugal compressor. Specifically, design specifications are adjusted depending on conditions, such as a type (physical characteristics) of working fluid, flow velocity (flow rate) of the working fluid, temperature of the working fluid, as well as a difference in surrounding conditions, such as the presence or absence of diffuser vanes and the presence or absence of a shroud, and required operating conditions.

### CITATION LIST

### Patent Literature

Patent document 1: Japanese laid-open patent publication No. 2020-051321
Patent document 2: Japanese laid-open patent publication No. 2009-057959

### SUMMARY OF INVENTION

### Technical Problem

The pump design process includes determining a part of a pump for adjusting a shape of a pump section having an impeller and a flow passage section that houses the impeller therein and determining an amount and direction of adjusting the shape of the pump section. However, it is difficult to predict how much of an effect it would have on improving the pump performance. Therefore, the pump design process largely depends on a designer's experience and intuition. In addition, the pump performance is required to satisfy not only the required specifications, but also multiple performance indexes, such as efficiency, shaft power, and NPSH required (Net Positive Suction Head required) at higher levels. However, these multiple performance indexes are in a trade-off relationship, and therefore it has been a very difficult task even for a skilled designer to derive the optimal solution for the shape of the pump.

In view of the above background, the present invention provides a machine-learning apparatus, a pump-performance prediction apparatus, an inference apparatus, a pump-shape designing apparatus, a machine-learning method, a pump-performance prediction method, an inference method, a pump-shape designing method, a machine learning program, a pump-performance prediction program, an inference program, and a pump-shape designing program capable of predicting a pump performance with high accuracy without relying on experience or intuition of a designer and capable of assisting a pump design process.

### Solution to Problem

In order to achieve the above object, a machine-learning apparatus according to an embodiment of the present invention comprises: a learning-data storage section that stores plural sets of learning data including input data and output data, the input data including shape parameters of a pump section having an impeller and a flow passage section in which the impeller is accommodated, the output data including pump performance of a pump having the pump section defined by the shape parameters; a machine-learning section configured to cause a learning model to learn a correlation between the input data and the output data by inputting the plural sets of the learning data to the learning model; and a learned-model storage section configured to store the learning model that has been caused to learn the correlation by the machine-learning section.

An embodiment of the present invention is a pump-shape designing apparatus for designing a shape of a pump section using a learning model generated by the machine-learning apparatus. The pump section includes an impeller and a flow passage section in which the impeller is accommodated. The pump-shape designing apparatus includes: a required-specification receiving section configured to receive required specifications for a pump performance of a pump; a candidate extracting section configured to extract candidates as specification satisfactory candidates from among multiple candidates for a plurality of pump sections defined by different shape parameters of the plurality of pump sections, the candidates as the specification satisfactory candidates being candidates corresponding to pump performances which are inferred by inputting the shape parameters into the learning model for each candidate and satisfy the required specifications; a selection receiving section configured to receive a candidate as a selection candidate selected from the specification satisfactory candidates; and an information providing section configured to provide design information including the shape parameters defining the pump section of the selection candidate and the pump performance of the pump having the pump section corresponding to the selection candidate.

### Advantageous Effects of Invention

The machine-learning apparatus according to the embodiment of the present invention can provide the learning model that can infer (or predict) a pump performance of a pump having a pump section with high accuracy from the shape parameters of the pump section, without relying on experience or intuition of a designer. Furthermore, the pump-shape designing apparatus according to the embodiment of the present invention can assist the pump design process by using the learning model to extract the specification satisfactory candidates that satisfy the required specifications, and providing the design information to the selection candidate selected from the specification satisfactory candidates.

Objects, configurations, and effects other than those described above will be made clear in detailed descriptions of the invention described below.

### BRIEF DESCRIPTION OF DRAWINGS

FIG. 1 is an overall diagram showing an example of a pump designing system 1;

FIG. 2 is a schematic configuration diagram showing an example of a pump 2;

FIG. 3A is a perspective view showing an example of an impeller 20;

FIG. 3B is a meridional cross-sectional view showing an example of the impeller 20;

FIG. 4 is an explanatory diagram showing an example of meridian-plane shape parameters of a pump section;

FIG. 5 is a graph showing an example of a performance curve representing a pump performance of the pump 2;

FIG. 6 is a hardware configuration diagram showing an example of a computer 900;

FIG. 7 is a block diagram showing an example of a machine-learning apparatus 3;

FIG. 8 is a schematic diagram showing an example of data (supervised learning) used in the machine-learning apparatus 3 and an example of a learning model 10;

FIG. 9 is a schematic diagram showing an example of a neural network model that constitutes the learning model used in the machine-learning apparatus 3;

FIG. 10 is a flowchart showing an example of a machine-learning method performed by the machine-learning apparatus 3;

FIG. 11 is a block diagram showing an example of a pump-shape designing apparatus 4;

FIG. 12 is a flowchart showing an example of a pump-shape designing method performed by the pump-shape designing apparatus 4;

FIG. 13 is a flowchart (continuation of FIG. 12) showing an example of the pump-shape designing method performed by the pump-shape designing apparatus 4;

FIG. 14 is a screen configuration diagram showing an example of a selection-candidate input screen 14 based on scatter-diagram information; and

FIG. 15 is a screen configuration diagram showing an example of a selection-candidate input screen 14 based on self-organizing map information.

### DESCRIPTION OF EMBODIMENTS

Embodiments for practicing the present invention will be described below with reference to the drawings. In the following descriptions, scope necessary for the descriptions to achieve the object of the present invention will be schematically shown, scope necessary for the descriptions of relevant parts of the present invention will be mainly described, and parts omitted from the descriptions will be based on known technology.

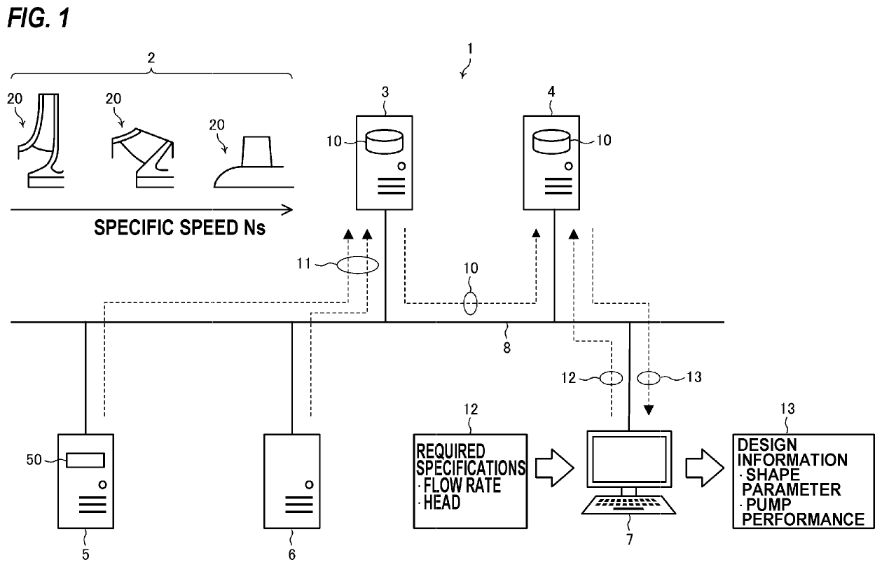

FIG. 1 is an overall diagram showing an example of a pump designing system 1. The pump designing system 1 serves as a system that assists a designer in design processes of designing a shape of a pump section that includes an impeller 20 for a pump 2 and a flow passage section in which the impeller 20 is accommodated. Examples of the pump 2 include a centrifugal pump (including a volute pump, a volute pump with guide vanes, etc.), a mixed flow pump (including a volute mixed-flow pump, a mixed-flow pump with guide vanes, etc.), and an axial flow pump, which are classified according to a flow rate Q, a head H, and a magnitude of a specific speed Ns calculated from a rotational speed N. The pump designing system 1 is not limited for the above types and can be used for designing any type of turbo pump.

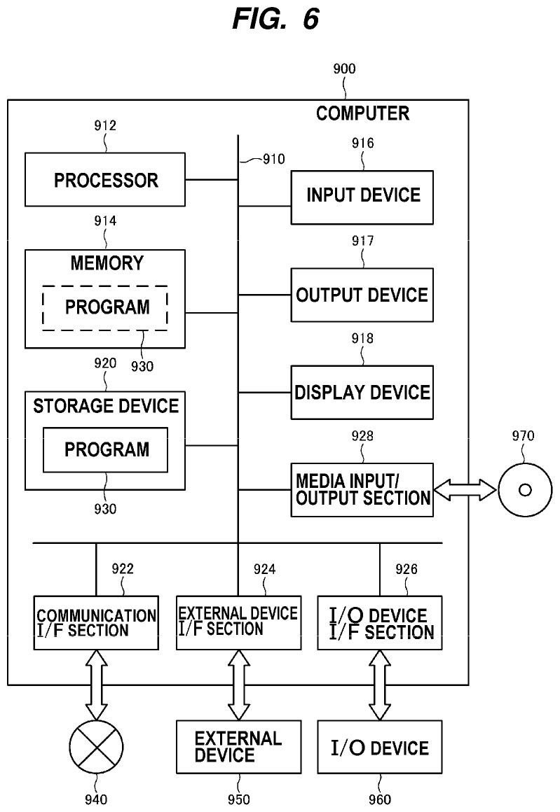

The pump designing system 1 includes, as its main components, a machine-learning apparatus 3, a pump-shape designing apparatus 4, a design database apparatus 5, a CFD analysis apparatus 6, and a designer terminal apparatus 7. Each of the apparatuses 3 to 7 is configured to include, for example, a general-purpose or dedicated computer (see FIG. 6 described later), and is coupled to a wired or wireless network 8 to mutually transmit and collect various data (some of data are shown in FIG. 1). Before details of the apparatuses 3 to 7 are explained, the schematic configuration of the pump 2 will be explained.

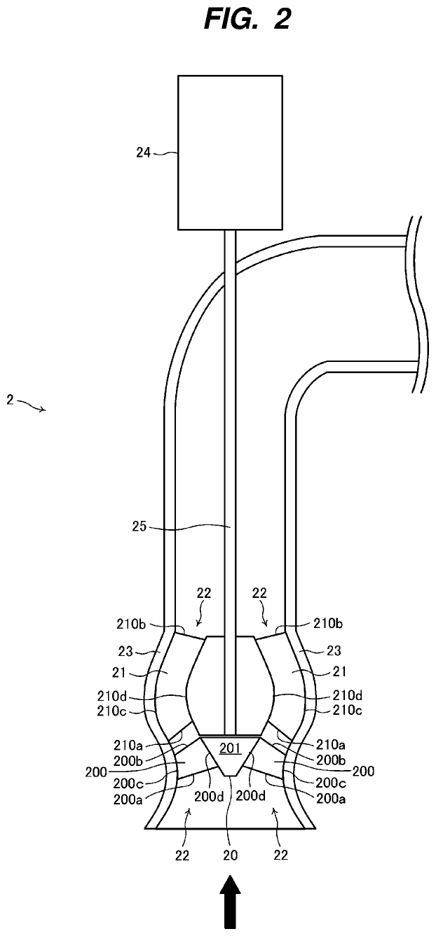

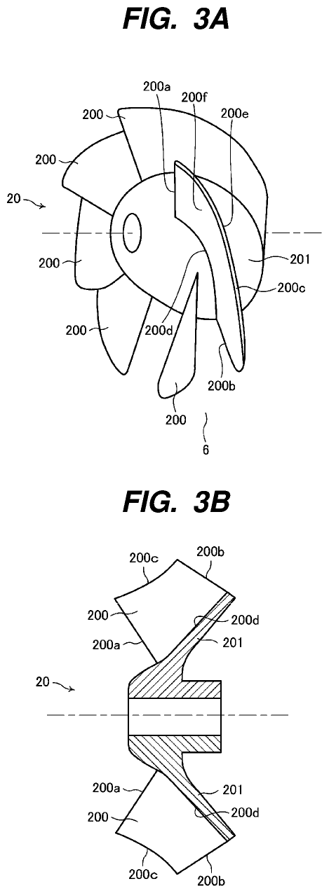

FIG. 2 is a schematic configuration diagram showing an example of the pump 2. FIG. 3 shows an example of the impeller 20. Specifically, FIG. 3A is a perspective view and FIG. 3B is a meridional cross-sectional view. The pump 2 shown in FIG. 2 is an example of a type of the pump 2 designed by the pump-shape designing apparatus 4. The pump 2 shown in FIG. 2 is a vertical-axis mixed flow pump of an open type that does not have a shroud on a tip side (or a distal-end side) of each blade 200 of the impeller 20.

The pump 2 mainly includes the impeller 20 having a plurality of blades 200 and a hub 201, guide vanes 21 (e.g., diffusers or guide vanes) arranged at a fluid discharge side of the impeller 20, a casing 23 that houses the impeller 20 therein and forms flow passage sections 22 through which fluid flows, a drive machine 24 that is a rotating drive source for the pump 2, and a rotation shaft 25 that couples the hub 201 to the drive machine 24. The pump 2 may be of a closed type in which the impeller 20 has a shroud, or may include an inducer (auxiliary impeller) provided upstream of the impeller 20.

The hub 201 of the impeller 20 is attached to the rotation shaft 25. The plurality of blades 200 are arranged in a circumferential direction around the rotation shaft 25. The impeller 20 is manufactured using any material and any manufacturing method depending on the shape of the impeller 20. Each blade 200 has a leading edge 200a located at a suction side of the pump 2, a trailing edge 200b located at a discharge side of the pump 2, a tip-side edge 200c facing the casing 23 and located at a tip side of the blade 200, and a hub-side edge 200d located at a boundary surface of the hub 201 and is located at a hub side of the blade 200. Furthermore, the blade 200 has a pressure surface 200e located at a front side in the rotational direction and a suction pressure surface 200f located at a back side in the rotational direction when the impeller 20 is rotated by the drive machine 24 via the rotation shaft 25.

The guide vanes 21 are arranged in the circumferential direction around the rotation shaft 25, and function as stationary vanes. Each guide vane 21 includes a leading edge 210a located at the suction side of the pump 2, a trailing edge 210b located at the discharge side of the pump 2, an shroud edge 210c located at a casing-23-side, and an hub edge 210d located at a rotation-shaft-25-side. The flow passage sections 22 are spaces through which the fluid flows. When the pump 2 includes the guide vanes 21, the guide vanes 21 are regarded as elements constituting part of the flow passage sections 22. Furthermore, when the pump 2 is a volute pump, a vortex casing called a volute is provided around the impeller 20, and this volute may also be regarded as an element constituting part of the flow passage sections 22. In this case, a volute tongue can perform the same function as the guide vanes 21.

In designing of the impeller 20, shape parameters that define a three-dimensional shape of the pump section including the impeller 20 and the flow passage sections 22 are determined so as to satisfy required specifications 12 for the pump performance of the pump 2. The shape parameters of the pump section are roughly classified into meridional shape parameters of the pump section that characterize a meridian shape, and 3D blade surface shape parameters of the pump section that characterize a 3D blade shape. The shape parameters of the pump section may include only shape parameters for the impeller 20, or only shape parameters for the flow passage sections 22, or shape parameters for the impeller 20 and the flow passage sections 22.

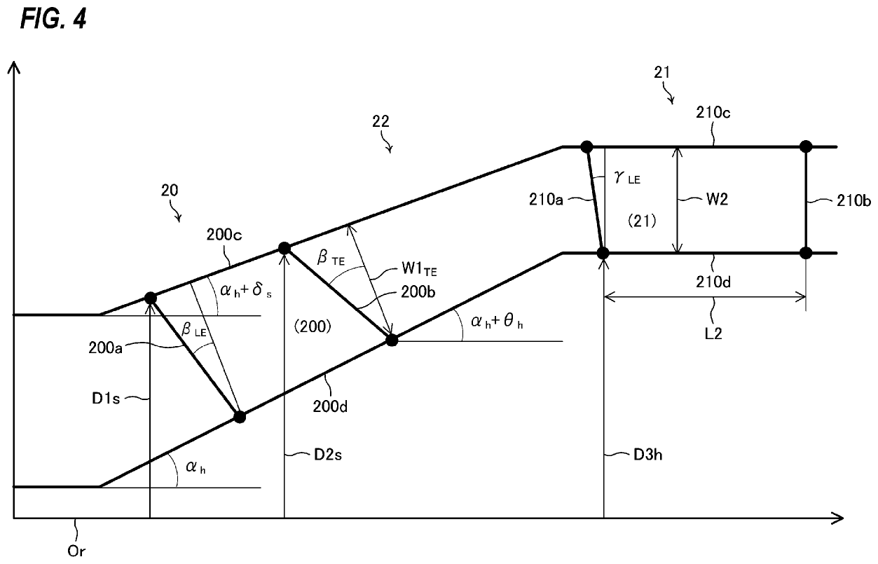

FIG. 4 is an explanatory diagram showing examples of the meridional shape parameters for the pump section. The meridional cross-sectional view shown in FIG. 4 is a diagram in which the shape of the blade 200 is rotationally projected along the rotation shaft 25, and the rotationally-projected shape of the blade 200 is superimposed on a cross-section of the pump 2 taken along the rotation shaft 25.

The meridional shape parameters define mainly positions, angles, shapes, etc. of the leading edge 200a, the trailing edge 200b, the tip-side edge 200c, and the hub-side edge 200d of the impeller 20, and define positions, angles, shapes, etc. of the flow passage sections 22 in the meridional cross-sectional view shown in FIG. 4. Therefore, the meridional shape parameters define not only the meridional-plane shape of the impeller 20 but also the meridional-plane shapes of the flow passage sections 22 in which the impeller 20 is accommodated. When the pump 2 has the guide vanes 21 that are regarded as part of the flow passage sections 22, the meridional shape parameters may define positions, angles, shapes, etc. of the leading edge 210a, the trailing edge 210b, the shroud edge 210c, and the hub edge 210d of each guide vane 21. When the pump 2 is a volute pump, the meridional shape parameters may define position, angle, shape, etc. of the volute (including the volute tongue) in a meridional plane cross-sectional view.

Examples of the meridional shape parameters may include an outer diameter D1s of the leading edge 200a of the impeller 20, a maximum diameter D2s of the impeller 20 corresponding to an outer diameter of the trailing edge 200b of the impeller 20, a flow passage width W1_{TE} of the flow passage section 22 where the trailing edge 200b is located among the flow passage sections 22 accommodating the impeller 20 therein, an inclination angle αₕ of the hub-side edge 200d at the suction side of the impeller 20, an inclination angle δₛ (an angle relative to the inclination angle αₕ) of the tip-side edge 200c at the suction side of the impeller 20, an inclination angle θₕ (an angle relative to the inclination angle αₕ) of the tip-side edge 200c at the discharge side of the impeller 20, an inclination angle β_{LE} of the leading edge 200a of the impeller 20, and an inclination angle β_{TE} of the trailing edge 200b of the impeller 20. The maximum diameter D2s of the impeller 20 is the outer diameter of the trailing edge 200b, and is a vertical distance from a rotation center Or of the impeller 20 to an intersection between the trailing edge 200b and the tip-side edge 200c.

In addition to the above, the meridional shape parameters may further include an inner diameter D3h of a stationary flow-passage section in which the leading edge 210a of the guide vane 21 is located. The stationary flow-passage section is one of the flow passage sections 22 in which the impeller 20 is accommodated and is located at the discharge side of the impeller 20. The meridional shape parameters may further include a flow passage width W2 of the stationary flow-passage section located at the discharge side of the impeller 20 where the guide vane 21 is located, an inclination angle γ_{LE} of the leading edge 210a of the guide vane 21, and a distance L2 between the leading edge 210a and the trailing edge 210b of the guide vane 21. In FIG. 4, the leading edge 200a, the trailing edge 200b, the tip-side edge 200c, and the hub-side edge 200d of the impeller 20, and the leading edge 210a, the trailing edge 210b, the shroud edge 210c, and the hub edge 210d of the guide vane 21 are depicted with linear lines. It is noted, however, that all or part of them may be curved, and the meridional shape parameters may include a parameter that defines the curved shape.

The 3D blade surface shape parameters may define a blade angle distribution and a blade thickness distribution between the blade leading edge 200a and the blade trailing edge 200b along the tip-side edge 200c. Shapes of the distributions may be defined by parameters that express a straight line, a polynomial curve, or free curve that is a combination of Bezier curves or the like. Such 3D blade surface shape parameters may be determined according to a design method disclosed in known document 1 (Chapter 7 Design of the hydraulic components, Gulich, J. F., 2010, Centrifugal Pumps, 2nd Edition, Springer Publications, Berlin). Shapes of such distributions may further be defined along the hub-side edge 200d, or may further be defined at an intermediate position between the tip-side edge 200c and the hub-side edge 200d. As described above, the 3D blade surface shape parameters are parameters that mainly define shape of curved surface (blade surface) formed by the pressure surface 200e and the suction pressure surface 200f of the impeller 20 in FIG. 3A. Specifically, the 3D blade surface shape parameters define the shape of the blade surface of the impeller 20. When the pump 2 has the guide vanes 21 regarded as part of the flow passage sections 22, the 3D blade surface shape parameters may define a shape of vane surface of each guide vane 21. Furthermore, when the pump 2 is the volute pump, the 3D blade surface shape parameters may define the shape of the volute (including the volute tongue).

The 3D blade surface shape parameters may define a blade loading distribution and a blade thickness distribution between the blade leading edge 200a and the blade trailing edge 200b along the tip-side edge 200c. Shapes of the distributions may be defined by parameters that express a straight line, a polynomial curve, or free curve that is a combination of Bezier curves or the like. Such 3D blade surface shape parameters may be determined according to a design method disclosed in known document 2 (Goto, A. et al., 2002, Hydrodynamic Design System for Pumps Based on 3-D CAD, CFD, and Inverse Design Method, Journal of Fluids Engineering, ASME, Vol. 124, p. 329-335), which may be hereinafter referred to as inverse solution method. Shapes of such distributions may further be defined along the hub-side edge 200d, or may further be defined at an intermediate position between the tip-side edge 200c and the hub-side edge 200d. As described above, the 3D blade surface shape parameters are parameters that mainly define shape of curved surface (blade surface) formed by the pressure surface 200e and the suction pressure surface 200f of the impeller 20 in FIG. 3A. Specifically, the 3D blade surface shape parameters define the shape of the blade surface of the impeller 20. When the pump 2 has the guide vanes 21 regarded as part of the flow passage sections 22, the 3D blade surface shape parameters may define a shape of vane surface of each guide vane 21. Furthermore, when the pump 2 is the volute pump, the 3D blade surface shape parameters may define the shape of the volute (including the volute tongue).

In any method of defining the 3D blade surface shape parameters, it is necessary to define parameter that defines energy that is imparted from the impeller 20 to the fluid, i.e., an average angular momentum RVtbase of the fluid per unit mass at the trailing edge 200b (blade outlet) of the impeller 20.

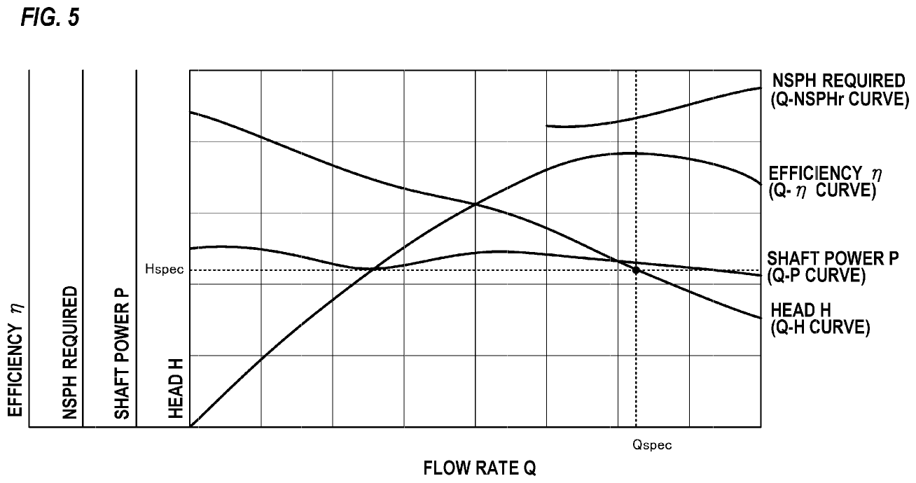

FIG. 5 is a graph showing an example of a performance curve representing the pump performance of the pump 2. The pump performance includes a plurality of performance indexes that evaluate the performance of the pump 2 from various viewpoints.

The pump performance is determined by, for example, a performance curve (Q-H curve) based on a relationship between flow rate Q (i.e., a discharge amount of the pump 2) and head H, a performance curve (Q-P curve) based on a relationship between flow rate Q and shaft power P, a performance curve (Q-NPSHr curve) based on a relationship between flow rate Q and NPSH required (Net Positive Suction Head required, NPSHr), and a performance curve (Q-η curve) based on a relationship between flow rate Q and efficiency η. It is noted that a performance curve other than the performance curves described above may be used as performance index representing the pump performance.

The pump performance is further represented by a maximum head ratio and a maximum shaft-power ratio. The maximum head ratio represents a ratio of a maximum head on the Q-H curve to a head at a design flow rate (a flow rate Qspec which will be described later). The maximum shaft-power ratio represents a ratio of a maximum shaft power on the Q-P curve to a shaft power at the design flow rate (flow rate Qspec which will be described later).

In the design of the impeller 20, the shape parameters for the pump section are determined to satisfy the required specifications 12 for the pump performance. The required specifications 12 are specified by at least one performance index. For example, the required specifications 12 may be specified by the relationship between the flow rate Q and the head H, e.g., the specific flow rate Qspec and a head Hspec corresponding to the specific flow rate Qspec, as shown in FIG. 5.

Hereinafter, returning back to FIG. 1, each of the apparatuses 3 to 7 constituting the pump designing system 1 will be explained.

The machine-learning apparatus 3 operates as a main configuration for a learning phase in machine learning. For example, the machine-learning apparatus 3 obtains learning data 11 from the design database apparatus 5 and the CFD analysis apparatus 6, and performs the machine learning to create a learning model 10 used in the pump-shape designing apparatus 4. The learning model 10 as the learned model is provided to the pump-shape designing apparatus 4 via the network 8, a storage medium, or the like. The machine-learning apparatus 3 employs, for example, supervised learning as the machine-learning method.

The pump-shape designing apparatus 4 operates as a main configuration in an inference phase of the machine learning. The pump-shape designing apparatus 4 uses the learning model 10 generated by the machine-learning apparatus 3 to design the shape of the pump section composed of the impeller 20 and the flow passage sections 22. The pump-shape designing apparatus 4 receives, for example, the required specifications 12 for the pump performance of the pump 2 from the designer terminal apparatus 7, and outputs design information 13 based on candidates of the shape parameters defining the shape of the pump section that satisfies the required specifications 12. The required specifications 12 are specified (or designated) by specific values or ranges for one or more performance indexes representing the pump performance. For example, as shown in FIG. 5, the required specifications 12 are specified (or designated) by the flow rate Qspec and the head Hspec. The design information 13 includes the shape parameters that define the pump section and the pump performance of the pump 2 having that pump section.

The design database apparatus 5 stores previously designed data 50 therein. The previously designed data 50 includes the shape parameters of the pump section of the pump 2 that has been designed by a designer (or other designer) through trial and error in the past, and further includes evaluation results of the pump performance of that pump 2 that has been evaluated through experiments using an actual pump or a model of the pump 2 or high-precision simulation or the like. The previously designed data 50 is used as the learning data 11 by the machine-learning apparatus 3.

The CFD analysis apparatus 6 is configured to perform simulation based on computational fluid dynamics (CFD) to calculate the pump performance of the pump 2 having the pump section defined by predetermined shape parameters. Furthermore, the CFD analysis apparatus 6 is configured to determine shape parameters that satisfy the required specifications 12 for a specific pump performance using an arbitrary design method, such as a forward solution method or the inverse solution method. The CFD analysis apparatus 6 calculates another pump performance (i.e., a pump performance other than the specific pump performance) of the pump 2 having the pump section defined by the determined shape parameters. Results of the simulation performed by the CFD analysis apparatus 6 are used as the learning data 11 by the machine-learning apparatus 3.

The designer terminal apparatus 7 is a terminal device used by a designer. The pump-shape designing apparatus 4 receives various input operations (for example, required specifications 12 and selection of a candidate for the shape parameters that satisfy the required specifications 12) via a display screen of an application or a browser or the like. The pump-shape designing apparatus 4 displays various information (for example, visualized information based on the candidate for the shape parameters, the design information 13, etc.) on the display screen. Although the single designer terminal apparatus 7 is shown in the embodiment of FIG. 1, a plurality of designer terminal apparatuses 7 may be coupled to the pump designing system 1. Furthermore, the designer terminal apparatus 7 may be used by any user other than the designer.

FIG. 6 is a hardware configuration diagram showing an example of a computer 900. Each of the machine-learning apparatus 3, the pump-shape designing apparatus 4, the design database apparatus 5, the CFD analysis apparatus 6, and the designer terminal apparatus 7 is configured by general-purpose or dedicated computer 900.

As shown in FIG. 6, main components of the computer 900 include buses 910, a processor 912, a memory 914, an input device 916, an output device 917, a display device 918, a storage device 920, a communication I/F (interface) section 922, an external device I/F section 924, an I/O (input/output) device I/F section 926, and a media input/output section 928. The above components may be omitted as appropriate depending on an application in which the computer 900 is used.

The processor 912 includes one or more arithmetic processing unit(s) (CPU (Central Processing Unit), MPU (Micro-processing unit), DSP (digital signal processor), GPU (Graphic cs Processing Unit), etc.), and operates as a controller configured to control the entire computer 900. The memory 914 stores various data and programs 930, and includes, for example, a volatile memory (DRAM, SRAM, etc.) that functions as a main memory, a non-volatile memory (ROM), a flash memory, etc.

The input device 916 includes, for example, a keyboard, a mouse, a numeric keypad, an electronic pen, etc., and functions as an input section. The output device 917 includes, for example, a sound (voice) output device, a vibration device, etc., and functions as an output section. The display device 918 includes, for example, a liquid crystal display, an organic EL display, electronic paper, a projector, etc., and functions as an output section. The input device 916 and the display device 918 may be configured integrally, such as a touch panel display. The storage device 920 includes, for example, HDD (Hard Disk Drive), SSD (Solid State Drive), etc., and functions as a storage section. The storage device 920 stores various data necessary for executing the operating system and the programs 930.

The communication I/F section 922 is coupled to a network 940, such as the Internet or an intranet (which may be the same as the network 8 in FIG. 1), in a wired manner or a wireless manner, and transmits and receives data to and from another computer according to a predetermined communication standard. It functions as a communication unit that sends and receives information. The external device I/F section 924 is coupled to an external device 950, such as camera, printer, scanner, reader/writer, etc. in a wired manner or a wireless manner, and serves as a communication section that transmits and receives data to and from the external device 950 according to a predetermined communication standard. The I/O device I/F unit 926 is coupled to I/O device 960, such as various sensors or actuators, and functions as a communication unit that transmits and receives various signals, such as detection signals from the sensors or control signals to the actuators, and data to and from the I/O device 960. The media input/output unit 928 is constituted of a drive device, such as a DVD (Digital Versatile Disc) drive or a CD (Compact Disc) drive, and writes and reads data into and from medium (non-transitory storage medium) 970, such as a DVD or a CD.

In the computer 900 having the above configurations, the processor 912 calls the program 930 stored in the storage device 920 into the memory 914 and executes the program 930, and controls each part of the computer 900 via the buses 910. The program 930 may be stored in the memory 914 instead of the storage device 920. The program 930 may be stored in the medium 970 in an installable file format or an executable file format, and may be provided to the computer 900 via the media input/output unit 928. The program 930 may be provided to the computer 900 by being downloaded via the network 940 and the communication I/F unit 922. The computer 900 performs various functions realized by the processor 912 executing the programs 930. The computer 900 may include hardware, such an FPGA (field-programmable gate array), an ASIC (application specific integrated circuit), etc. for executing the above-described various functions.

The computer 900 is, for example, a stationary computer or a portable computer, and is an electronic device in arbitrary form. The computer 900 may be a client computer, a server computer, or a cloud computer. The computer 900 may be applied to devices other than the machine-learning apparatus 3, the pump-shape designing apparatus 4, the design database apparatus 5, the CFD analysis apparatus 6, and the designer terminal apparatus 7.

### (Machine-Learning Apparatus 3)

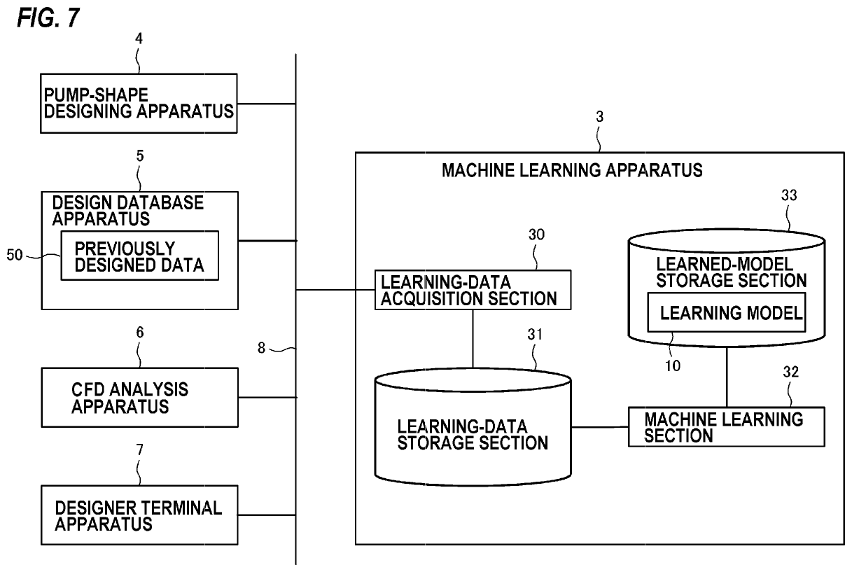

FIG. 7 is a block diagram showing an example of the machine-learning apparatus 3. The machine-learning apparatus 3 includes a learning-data acquisition section 30, a learning-data storage section 31, a machine-learning section 32, and a learned-model storage section 33. The machine-learning apparatus 3 may be constructed by the computer 900 shown in FIG. 6.

The learning-data acquisition section 30 is coupled to various external devices via the network 8. The learning-data acquisition section 30 is an interface unit configured to obtain the learning data 11 comprising the input data including the shape parameters of the pump section and the output data including the pump performance. The external devices include the pump-shape designing apparatus 4, the design database apparatus 5, the CFD analysis apparatus 6, the designer terminal apparatus 7, etc. The external devices may be a part of these apparatuses. The learning-data acquisition section 30 may further be coupled to other devices.

Two examples will be illustrated below as methods for the learning-data acquisition section 30 to acquire the learning data 11. In a first method, the learning-data acquisition section 30 receives the previously designed data 50 from the design database apparatus 5, and obtains the learning data 11 based on the shape parameters and the evaluation results of the pump performance included in the previously designed data 50. In a second method, the learning-data acquisition section 30 cooperates with the CFD analysis apparatus 6 to execute a simulation while changing simulation conditions as appropriate, thereby acquiring plural sets of learning data 11. For example, the learning-data acquisition section 30 generates a plurality of simulation conditions by varying the shape parameters within a predetermined range, and calculates the pump performance by the simulation for each simulation condition to thereby obtain plural sets of learning data 11. Furthermore, the learning-data acquisition section 30 generates a plurality of simulation conditions by varying specific pump performance within a predetermined range, and calculates the shape parameters by the simulation for each simulation condition to thereby obtain plural sets of learning data 11.

The learning-data acquisition section 30 obtains plural sets of learning data 11 by repeatedly performing the above-described methods or by appropriately combining the above-described methods. The plural sets of learning data 11 are acquired such that the specific speeds Ns of the pump 2 are distributed within a predetermined range (for example, 50 to 4000). It is noted that the learning-data acquisition section 30 may employ other method different from the above-described methods.

The learning-data storage section 31 is a database that stores the plural sets of learning data 11 obtained by the learning-data acquisition section 30. The specific configuration of the database that constitutes the learning-data storage section 31 may be designed as appropriate.

The machine-learning section 32 performs the machine learning using the plural sets of learning data 11 stored in the learning-data storage section 31. Specifically, the machine-learning section 32 inputs the plural sets of learning data 11 to the learning model 10 and causes the learning model 10 to learn the correlation between input data and output data included in the learning data 11 to thereby create the learning model 10 as a learned model. In this embodiment, a neural network is employed as the learning model 10 that realizes the machine learning (supervised learning) performed by the machine-learning section 32.

The learned-model storage section 33 is a database that stores the learning model 10 as a learned model created by the machine-learning section 32. The learning model 10 as the learned model stored in the learned-model storage section 33 is provided to a real system (for example, the pump-shape designing apparatus 4) via the network 8, a storage medium, or the like. Although the learning-data storage section 31 and the learned-model storage section 33 are shown as separate storage sections in FIG. 7, they may be configured as a single storage section.

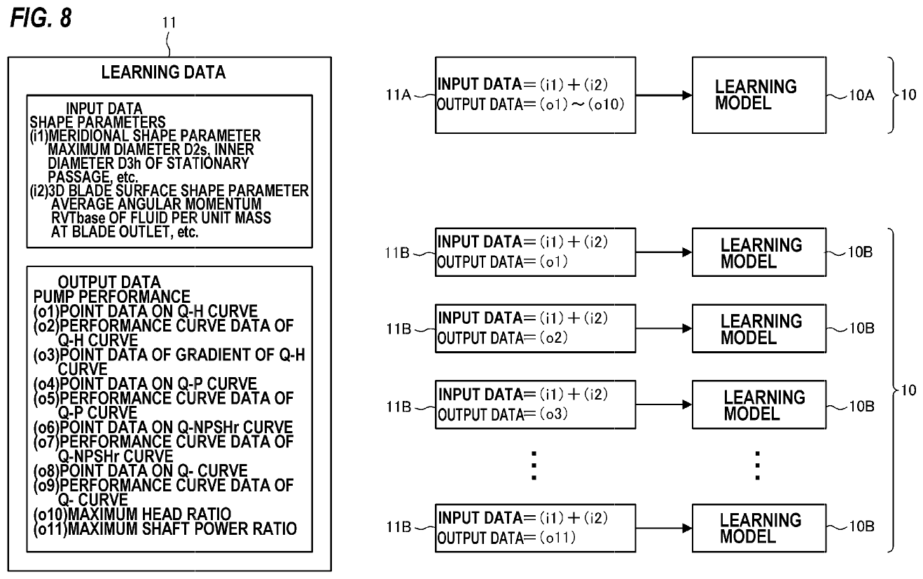

FIG. 8 is a schematic diagram showing an example of data (supervised learning) used by the machine-learning apparatus 3 and an example of the learning model 10. The learning data 11 is composed of input data including the shape parameters of the pump section and output data including the pump performance of the pump 2. The learning data 11 is data used as teaching data (or training data), verification data, and test data in supervised learning. The output data is used as ground-truth label or correct label in supervised learning.

The input data includes, as the shape parameters of the pump section, (i1) meridional shape parameter of the pump section and (i2) 3D blade surface shape parameter of the pump section. The input data may preferably include the meridional shape parameters including at least the maximum diameter D2s of the impeller 20 and the inner diameter D3h of the stationary flow-passage section located at the discharge side of the impeller 20, and the 3D blade surface shape parameter including at least the average angular momentum RVtbase of the fluid per unit mass at the trailing edge 200b (at the blade outlet) of the impeller 20.

The output data includes at least one of the following performance indexes representing the pump performance of the pump 2.
(o1) point data representing an arbitrary point on Q-H curve
(o2) performance curve data representing Q-H curve
(o3) point data of gradient of Q-H curve
(o4) point data representing an arbitrary point on Q-P curve
(o5) performance curve data representing Q-P curve
(o6) point data representing an arbitrary point on Q-NPSHr curve
(o7) performance curve data representing Q-NPSHr curve
(o8) point data representing an arbitrary point on Q-η curve
(o9) performance curve data representing Q-η curve
(o10) maximum head ratio
(o11) maximum shaft-power ratio

The performance curve data is composed of point-sequence data, i.e., a set of point data representing values of the flow rate Q at multiple flow-rate segments divided at predetermined intervals.

The input data is input to the learning model 10, and the learning model 10 outputs performance index(es) representing the pump performance as the output data corresponding to the input data. The learning model 10 may be composed of a single learning model 10A that outputs all of the performance indexes (o1) to (o11), or may be composed of multiple learning models 10B that output the performance indexes (o1) to (o11), respectively. Learning data 11A in the case of the single learning model 10A includes all of the performance indexes (o1) to (o11) as the output data. Learning data 11B in the case of the multiple learning models 10B includes each of the performance indexes (o1) to (o11) as the output data.

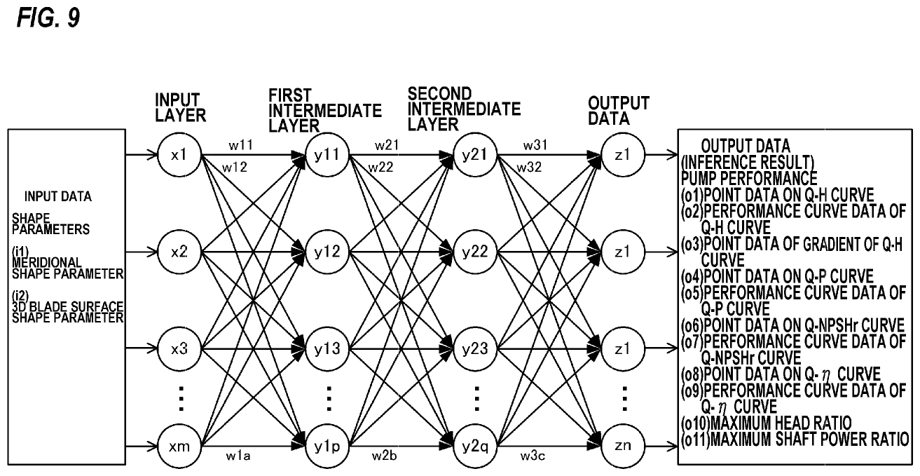

FIG. 9 is a schematic diagram showing an example of a neural network model that constitutes the learning model 10 used in the machine-learning apparatus 3. The learning model 10 is configured as a neural network model shown in FIG. 9, for example.

The neural network model includes m neurons (x1 to xm) in an input layer, p neurons (y11 to y1p) in a first hidden layer, q neurons (y21 to y2q) in a second hidden layer, and n neurons (z1 to zn) in an output layer.

Each neuron in the input layer is associated with a shape parameter as the input data included in the learning data 11. Each neuron in the output layer is associated with the output data included in the learning data 11, and each neuron in the output layer outputs a performance index representing a pump performance as an inference result. In the embodiment shown in FIG. 9, the learning model is composed of the single learning model 10A that outputs all of the performance indexes (o1) to (o11) as the output data. Pre-processing may be performed on the input data before being input to the input layer, and post-processing may be performed on the output data after being output from the output layer.

The first intermediate layer and the second intermediate layer are also called hidden layers, and the neural network may have a plurality of hidden layers in addition to the first intermediate layer and the second intermediate layer. Only the first intermediate layer may be a hidden layer. There are synapses connecting neurons in each layer between the input layer and the first hidden layer, between the first hidden layer and the second hidden layer, and between the second hidden layer and the output layer. Each synapse is associated with a weight wi (i is a natural number).

### (Machine-Learning Method)

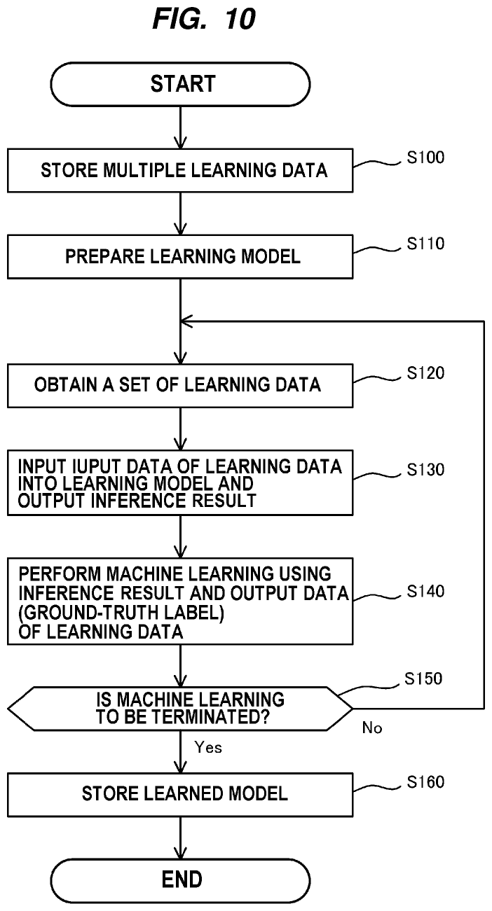

FIG. 10 is a flowchart illustrating an example of a machine-learning method performed by the machine-learning apparatus 3.

First, in step S100, the learning-data acquisition section 30 obtains a desired number of learning data 11 as advance preparation for starting the machine learning, and stores the obtained learning data 11 in the learning-data storage section. 31. The number of learning data 11 to be prepared may be set in consideration of the inference accuracy required for the learning model 10 finally obtained.

Next, in step S110, the machine-learning section 32 prepares the learning model 10 before learning for starting the machine learning. The learning model 10 prepared before learning in this embodiment is composed of the neural network model illustrated in FIG. 9, and the weight of each synapse is set to an initial value. Each neuron in the input layer is associated with a shape parameter as the input data included in the learning data 11. Pump performance as the output data included in the learning data 11 is associated with each neuron in the output layer.

Next, in step S120, the machine-learning section 32 randomly obtains, for example, one set of learning data 11 from the plural sets of learning data 11 stored in the learning-data storage section 31.

Next, in step S130, the machine-learning section 32 inputs the input data included in the one set of learning data 11 to the input layer of the prepared learning model 10 before learning (or during learning). As a result, the output data is output from the output layer of the learning model 10 as the inference result. However, the output data is generated by the learning model 10 before learning (or during learning). Therefore, in the state before learning (or during learning), the output data as the inference result may indicate different information from the output data (ground-truth label) included in the learning data 11.

Next, in step S140, the machine-learning section 32 performs the machine learning by comparing the output data (ground-truth label) included in the one set of learning data 11 acquired in the step S120 with the output data as the inference result output from the output layer in the step S130, and adjusting the weight wi of each synapse (backpropagation). In this way, the machine-learning section 32 causes the learning model 10 to learn the correlation between the input data and the output data.

Next, in step S150, the machine-learning section 32 determines whether or not a predetermined learning end condition is satisfied. For example, this determination is made based on an evaluation value of an error function based on the output data (ground-truth label) included in the learning data and the output data output as the inference result, or based on the remaining number of unlearned learning data stored in the learning-data storage section 31.

In step S150, if the machine-learning section 32 has determined that the learning end condition is not satisfied and the machine learning is to be continued (No in step S150), the process returns to the step S120, and the steps S120 to S140 are performed on the learning model 10 multiple times using the unlearned learning data 11. On the other hand, in step S150, if the machine-learning section 32 has determined that the learning end condition is satisfied and the machine learning is to be terminated (Yes in step S150), the process proceeds to step S160.

In step S160, the machine-learning section 32 stores, in the learned-model storage section 33, the learning model 10 as the learned model (adjusted weight parameter group) generated by adjusting the weight associated with each synapse. The sequence of machine-learning processes shown in FIG. 10 is completed. In the machine-learning method, the step S100 corresponds to a learning-data storing process, the steps S110 to S150 correspond to a machine-learning process, and the step S160 corresponds to a learned-model storing process.

As discussed above, the machine-learning apparatus 3 and the machine-learning method according to the embodiments can provide the learning model 10 that can infer (predict) the pump performance from the shape parameters of the pump section with high accuracy.

### (Pump-Shape Designing Apparatus 4)

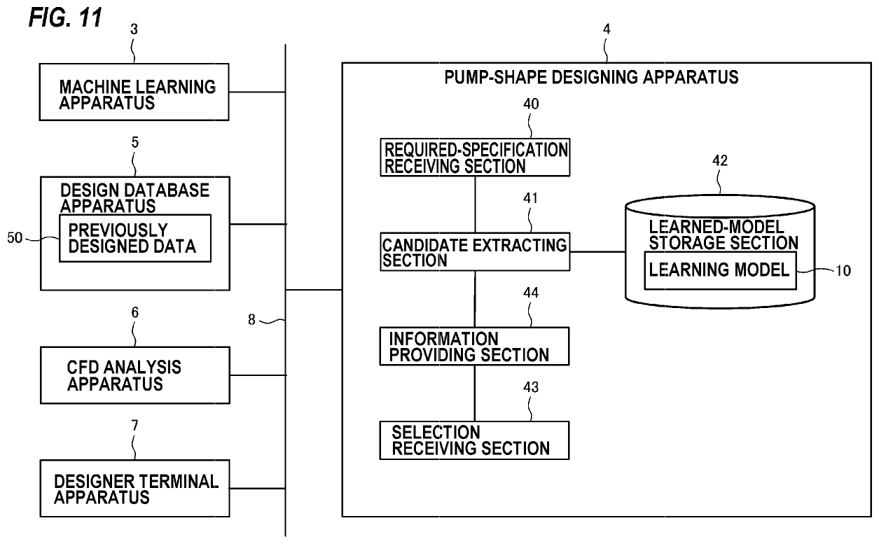

FIG. 11 is a block diagram showing an example of the pump-shape designing apparatus 4. The pump-shape designing apparatus 4 includes a required-specification receiving section 40, a candidate extracting section 41, a learned-model storage section 42, a selection receiving section 43, and an information providing section 44. The pump-shape designing apparatus 4 may include the computer 900 shown in FIG. 6.

The required-specification receiving section 40 is, for example, an interface unit that is coupled to the designer terminal apparatus 7 via the network 8 and is configured to receive required specifications 12 regarding the pump performance of the pump 2. For example, the required-specification receiving section 40 receives, from the designer terminal apparatus 7, the required specifications 12 of a design target input by a designer on a required-specification input screen displayed on the designer terminal apparatus 7.

The candidate extracting section 41 generates multiple candidates for a plurality of pump sections defined by different shape parameters of the pump sections, and inputs the shape parameters of each candidate into the learning model 10 as the input data for each candidate. The candidate extracting section 41 performs an inference process to infer the pump performance of the pump 2 having the pump section defined by the shape parameters of each candidate. Then, the candidate extracting section 41 extracts, from among the multiple candidates for the plurality of pump sections, candidates as specification satisfactory candidates corresponding to pump performances which are inferred in the above-described inference process and satisfy the required specifications 12 of the design target.

The learned-model storage section 42 is a database that stores the learning model 10 as the learned model. This learning model 10 is used in the inference process of the candidate extracting section 41. The learned-model storage section 42 may store at least one of the single learning model 10A and the plurality of sets of learning models 10B as the learning model 10, as shown in FIG. 8.

The selection receiving section 43 is, for example, an interface unit that is coupled to the designer terminal apparatus 7 via the network 8 and is configured to receive a candidate selected from the specification satisfactory candidates extracted by the candidate extracting section 41. For example, the selection receiving section 43 receives, from the designer terminal apparatus 7, a selection candidate information indicating a candidate selected by the designer from among the specification satisfactory candidates, and accepts the selected candidate as a selection candidate. The selection receiving section 43 may accept, as the selection candidate, a candidate input by the designer on the selection-candidate input screen displayed on the designer terminal apparatus 7. The selection-candidate input screen is configured to display, for example, a visualization screen (numerical-value screen, scatter-diagram screen, self-organizing map screen, etc.) of the specification satisfactory candidates based on visualized information (numerical-value information, scatter-diagram information, self-organizing map information, etc.) provided by the information providing section 44. The selection receiving section 43 may receive conditions for the selection candidate in advance, and may accept the selection candidate which is a specification satisfactory candidate that most matches the conditions.

The information providing section 44 provides the design information 13 to the designer terminal device 7. The design information 13 includes the shape parameters defining the impeller 20 corresponding to the selection candidate accepted by the selection receiving section 43, and further includes the pump performance of the pump 2 having the impeller 20 corresponding to the selection candidate. The information providing section 44 generates visualized information in which the performance indexes for the specification satisfactory candidates are visualized for the respective specification satisfactory candidates, and provides the visualized information to the designer terminal apparatus 7. The visualized information provided by the information providing section 44 may include numerical-value information that numerically expresses one performance index for the specification satisfactory candidate, scatter-diagram information that expresses two or three performance indexes for the specification satisfactory candidate in a scatter diagram, and self-organizing map information that expresses four or more performance indexes for specification satisfactory candidate in a self-organizing map. In addition to the numerical-value information, the scatter-diagram information, and the self-organizing map information, the information providing section 44 may further generate visualized information based on any visualization method that allows comparison of performance indexes, or may generate a plurality of visualized information by combining them. Furthermore, the performance index used when generating the numerical-value information, the scatter-diagram information, and the self-organizing map information may be selected by the designer or may be predetermined.

### (Pump-Shape Designing Method)

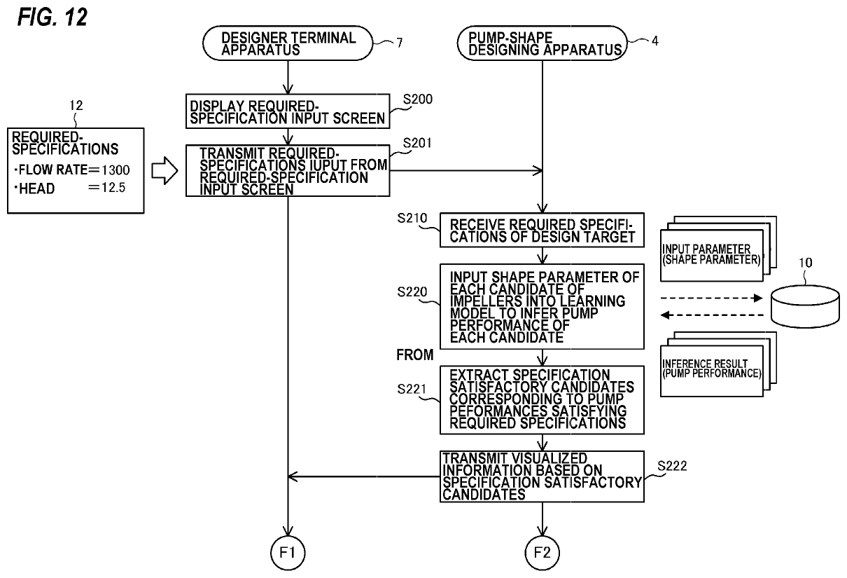

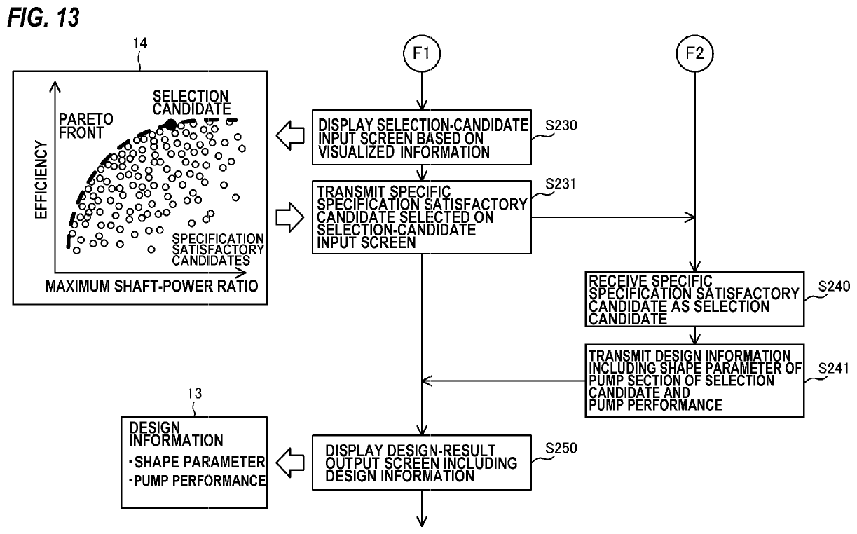

FIGS. 12 and 13 are flowcharts showing an example of the pump-shape designing method performed by the pump-shape designing apparatus 4.

First, in step S200, when the designer terminal apparatus 7 receives an input operation from the designer to start designing the pump 2, the designer terminal apparatus 7 displays the required-specification input screen. When the designer inputs the required specifications 12 for the pump performance to the required-specification input screen, the pump-shape designing apparatus 4 transmits the input required specifications 12 to the pump-shape designing apparatus 4 in step S201. When the required specifications include the specific flow rate Qspec and the head Hspec corresponding to the specific flow rate Qspec, the input required specifications are specified or designated by the flow rate Qspec=“1300” and the head Hspec=“12.5”, for example.

Next, in step S210, the required-specification receiving section 40 of the pump-shape designing apparatus 4 receives the required specifications 12 input by the designer from the designer terminal apparatus 7, thereby accepting the required specifications 12 of the design target.

Next, in step S220, the candidate extracting section 41 generates multiple candidates for a plurality of pump sections defined by different shape parameters, and inputs the shape parameters of each candidate as the input data into the learning model 10. The candidate extracting section 41 performs the inference process of inferring the pump performance of the pump 2 having the pump section defined by the shape parameters of each candidate. The pump performance to be inferred may include the Q-H curve, the Q-P curve, the Q-NPSHr curve, the Q-η curve, the maximum head ratio, and the maximum shaft-power ratio. The candidate extracting section 41 associates the shape parameters of each candidate with the pump performance and temporarily stores them.

Then, in step S221, the candidate extracting section 41 extracts, from among the multiple candidates for the plurality of pump sections, candidates as the specification satisfactory candidates corresponding to pump performances which are inferred in the inference process and satisfy the required specifications 12 of the design target. The specification satisfactory candidates extracted by the candidate extracting section 41 satisfy the required specifications 12 (e.g., the flow rate Qspec=“1300”, the head Hspec=“12.5”). Therefore, the specification satisfactory candidates pass through the specific point (Qspec, Hspec) on the H-Q curve. On the other hand, curve shapes of the H-Q curve other than the specific point are different. The Q-P curve, the Q-NPSHr curve, the Q-η curve, the maximum head ratio, and the maximum shaft-power ratio also have different pump performances.

Next, in step S222, the information providing section 44 generates the visualized information that visualizes the performance indexes for the specification satisfactory candidates extracted in the step S221, and transmits the visualized information to the designer terminal apparatus 7. The visualized information includes, for example, the numerical-value information, the scatter-diagram information, the self-organizing map information, etc. while in this embodiment, the visualized information is the numerical-value information or the self-organizing map information, which will be discussed below.

Next, in step S230, upon receiving the visualized information from the pump-shape designing apparatus 4, the designer terminal apparatus 7 displays the selection-candidate input screen based on the visualized information.

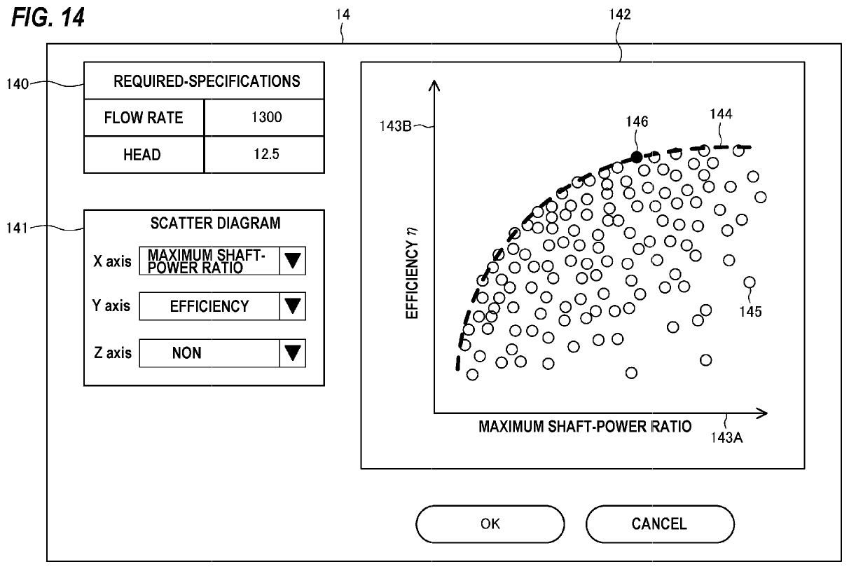

FIG. 14 is a screen configuration diagram showing an example of the selection-candidate input screen 14 based on the scatter-diagram information. When the visualized information is the scatter-diagram information, the selection-candidate input screen 14 based on the scatter-diagram information includes a required-specification display field 140 that displays the required specifications 12 of the design target, an axis display field 141 that displays the performance indexes assigned to axes of the scatter diagram, and a scatter-diagram display field 142 that displays the scatter diagram.

In the scatter-diagram display field 142, the multiple specification satisfactory candidates 145 are plotted as shown by white circles in FIG. 14 on the scatter diagram representing the maximum shaft-power ratio assigned to horizontal axis 143A and the efficiency η assigned to vertical axis 143B. A specific specification satisfactory candidate 146 can be selected from the multiple specification satisfactory candidates 145. The efficiency η represents a value of the efficiency η with respect to the flow rate Qspec on the Q-η curve.

In the multiple specification satisfactory candidates 145 that satisfy the required specifications 12, there is a trade-off relationship between a design request to reduce the maximum shaft-power ratio of the horizontal axis 143A and a design request to increase the efficiency η of the vertical axis 143B. Therefore, when the multiple specification satisfactory candidates 145 are plotted, a Pareto solution set (Pareto front) 144 is formed as shown by a broken line in FIG. 14. When the information providing section 44 generates the scatter-diagram information representing three performance indexes assigned to three axes (X axis, Y axis, Z axis), a three-dimensional scatter diagram is displayed on the selection-candidate input screen 14 shown in FIG. 14. The information providing section 44 may arbitrarily combine a plurality of performance indexes to generate the scatter-diagram information including a plurality of scatter diagrams. In this case, the selection-candidate input screen 14 may display the plurality of scatter diagrams arranged in the selection-candidate input screen 14. Furthermore, the axis display field 141 may be configured to be able to switch the performance indexes assigned to the axes of the scatter diagram. In this case, the information providing section 44 may assign the switched performance indexes to the axes and may regenerate the scatter-diagram information, so that the selection-candidate input screen 14 is updated.

Next, in step S240, the selection receiving section 43 receives from the designer terminal apparatus 7 the specific specification satisfactory candidate 146 selected by the designer on the selection-candidate input screen 14, and accepts the specific specification satisfaction candidate 146 as the selection candidate.

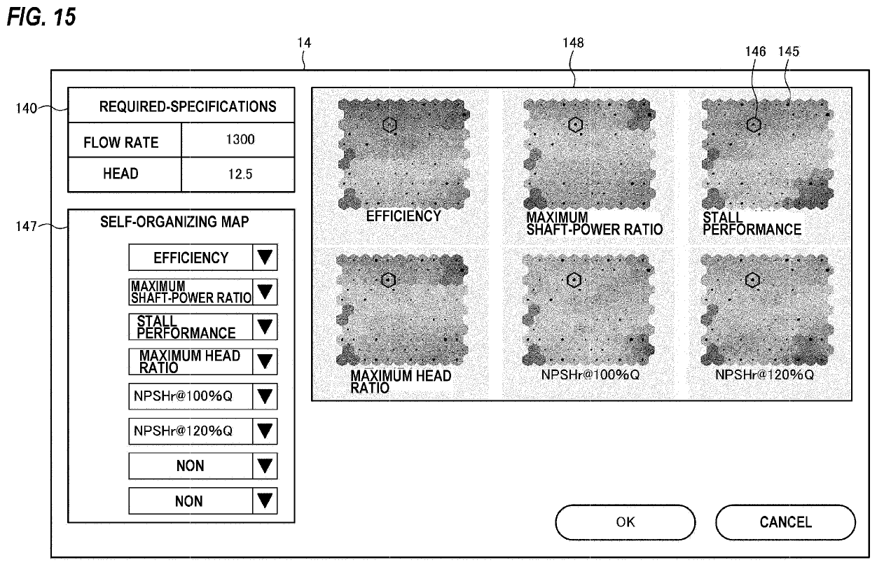

FIG. 15 is a screen configuration diagram showing an example of the selection-candidate input screen 14 based on the self-organizing map information. When the visualized information is the self-organizing map information, the selection-candidate input screen 14 based on the self-organizing map information includes a required-specification display field 140 that displays the required specifications 12 of the design target, an evaluation-value display field 147 that displays the performance indexes assigned to evaluation axes of self-organizing maps, and a self-organizing map display field 148.

The self-organizing map display field 148 displays, for example, six performance indexes including efficiency n, maximum shaft-power ratio, stall performance (representing the flow rate at which the gradient of the Q-H curve is positive), maximum head ratio, NPSHr for 100% of the flow rate Qspec, and NPSHr for 120% of the flow rate Qspec. These performance indexes are assigned to axes of the self-organizing maps. As shown in FIG. 15, multiple specification satisfactory candidates 145 are displayed as hexagonal cells. A specific specification satisfactory candidate 146 can be selected from the multiple specification satisfactory candidates 145. Cells displayed at the same position in the self-organizing maps represent the same specification satisfactory candidate 145. The evaluation-value display field 147 may be configured to be able to switch the performance indexes assigned to the self-organizing maps. In this case, the information providing section 44 may assign the switched performance indexes to the self-organizing maps and may regenerate the self-organizing diagram information, so that the selection-candidate input screen 14 is updated.

When the designer selects the specific specification satisfactory candidate (selection candidate) 146 from the multiple specification satisfactory candidates 145 on the selection-candidate input screen 14 (FIG. 13 shows an example of the selection-candidate input screen 14 based on the scatter-diagram information) as shown by a black circle in FIG. 14 or a black frame in FIG. 15, the pump-shape designing apparatus 4 transmits the selected specific specification satisfactory candidate 146 to the pump-shape designing apparatus 4 in step S231.

Next, in step S240, the selection receiving section 43 receives from the designer terminal apparatus 7 the specific specification satisfactory candidate 146 selected by the designer on the selection-candidate input screen 14, and accepts the specification satisfactory candidate 146 as the selection candidate.

Next, in step S241, the information providing section 44 transmits the design information 13 to the designer terminal device 7. The design information 13 includes the shape parameters defining the pump section corresponding to the selection candidate 146 accepted by the selection receiving section 43, and further includes the pump performance of the pump 2 having the pump section corresponding to the selection candidate 146. The pump performance included in the design information 13 is the inference result obtained when the candidate extracting section 41 inputs the shape parameters defining the pump section of the selection candidate 146 to the learning model 10 as the input data in the step S220.

Next, in step S250, upon receiving the design information 13 from the pump-shape designing apparatus 4, the designer terminal apparatus 7 displays a design-result output screen including the design information 13. The impeller 20 based on the shape parameters included in the design information 13 may be displayed in a three-dimensional manner on the design-result output screen. The pump performance included in the design information 13 may be graphically displayed as the Q-H curve, the Q-P curve, the Q-NPSHr curve, and the Q-η curve as shown in FIG. 5.

Then, by visually checking the design-result output screen, the designer confirms the shape parameters of the pump section designed by the pump-shape designing apparatus 4 and the pump performance of the pump 2 having the pump section, so that the pump-shape designing method shown in FIG. 12 is terminated. In the pump-shape designing method, the step S210 corresponds to a required-specification receiving process, the steps S220 and S221 correspond to a candidate extracting process, the step S240 corresponds to a selection receiving process, and the steps S222 and S241 correspond to an information providing process.

In the pump-shape designing method, various types of information (required specifications 12, the candidates, the specification satisfactory candidates, the selection candidate, the design information 13, etc.) generated or transmitted and received by the pump-shape designing apparatus 4 or the designer terminal apparatus 7 may be stored in at least one of the pump-shape designing apparatus 4 and the designer terminal apparatus 7. Furthermore, the pump-shape designing apparatus 4 may return to the step S200 or the step S230 after the step S250 in response to an input operation from the designer.

As described above, the pump-shape designing apparatus 4 and the pump-shape designing method according to the present embodiment can assist the design process of the pump 2 by extracting the specification satisfactory candidates that satisfy the required specifications 12 using the learning model 10, and providing the design information 13 for the selection candidate selected from among the specification satisfactory candidates. The pump-shape designing apparatus 4 can assist the design process of the pump 2 for a wide range of specific speeds Ns without receiving in advance the specific speed Ns or the designation of the pump 2 that serves as the baseline.

### Other Embodiments

The present invention is not limited to the above-described embodiments, and various modifications can be made and used without deviating from the scope of the present invention. All of them are included in the technical concept of the present invention.

In the above embodiments, the machine-learning apparatus 3 and the pump-shape designing apparatus 4 are configured as separate devices, while the machine-learning apparatus 3 and the pump-shape designing apparatus 4 may be configured as a single device. Furthermore, the machine-learning apparatus 3 and the pump-shape designing apparatus 4 may function as at least one of the design database apparatus 5, the CFD analysis apparatus 6, and the designer terminal apparatus 7.

In the embodiments described above, the neural network is employed as the learning model 10 that implements the machine learning performed by the machine-learning section 32, while other machine-learning model may be employed. Examples of the other machine-learning model include tree type (e.g., decision tree, regression tree), ensemble learning (e.g., bagging, boosting), neural network type including deep learning (e.g., recurrent neural network, convolutional neural network, LSTM), clustering type (e.g., hierarchical clustering, non-hierarchical clustering, k-nearest neighbor algorithm, k-means clustering), multivariate analysis (e.g., principal component analysis, factor analysis, logistic regression, Gaussian process regression), support vector machine, and regression-kriging.

In the above embodiments, the selection receiving section 43 receives the specification satisfactory candidate as the selection candidate selected by the designer on the selection-candidate input screen 14. In one embodiment, the selection receiving section 43 may receive conditions for the selection candidate in advance, and may accept the selection candidate which is a specification satisfactory candidate that most matches the conditions.

### (Machine Learning Program and Pump-Shape Designing Program)

The present invention can be provided in a form of a program (machine learning program) 930 for causing the computer 900 to execute each process included in the machine-learning method according to the above embodiments. Furthermore, the present invention can be provided in a form of a program (pump-shape designing program) 930 for causing the computer 900 to execute each process included in the pump-shape designing method according to the above embodiments.

### (Pump-Performance Prediction Apparatus, Pump-Performance Prediction Method, and Pump-Performance Prediction Program)

The present invention can be provided in a form of not only the pump-shape designing apparatus 4 (pump-shape designing method or pump-shape designing program) according to the above embodiments, but also in a form of a pump-performance prediction apparatus (a pump-performance prediction method or a pump-performance prediction program) that infers the pump performance of the pump 2 having the pump section including the impeller 20 and the flow passage section 22 in which the impeller 20 is accommodated. In that case, the pump-performance prediction apparatus (pump-performance prediction method or pump-performance prediction program) includes an input-data acquisition section (input-data acquisition process) that obtains input data including the shape parameters of the pump section, and an inference section (inference process) that inputs the obtained input data into the learning model 10 and infers the pump performance of the pump 2 having the pump section defined by the shape parameters.

### (Inference Apparatus, Inference Method, and Inference Program)

The present invention can be provided in a form of not only the pump-shape designing apparatus 4 (pump-shape designing method or pump-shape designing program) according to the above embodiments, but also in a form of an inference apparatus (inference method or inference program) used for inferring the pump performance of the pump 2 having the pump section including the impeller 20 and the flow passage section 22 in which the impeller 20 is accommodated. In that case, the inference apparatus (inference method or inference program) may include a memory and a processor. The processor may execute a series of processes. The series of processes includes an input-data acquisition processing (input-data acquisition process) that obtains the input data including the shape parameters of the pump section, and an inference processing (inference process) for inferring the pump performance of the pump 2 having the pump section defined by the shape parameters when the input date is obtained in the input-data acquisition processing.

The form of the inference apparatus (inference method or inference program) can be applied to various devices more easily than when the pump-performance prediction apparatus is implemented. It is readily understood by a person skilled in the art that the inference method performed by the inference section of the pump-performance prediction apparatus may be applied with use of the learning model 10 as the learned model generated by the machine-learning apparatus 3 and the machine-learning method according to the above embodiments when the inference apparatus (inference method or inference program) infers the pump performance.

### INDUSTRIAL APPLICABILITY

The present invention is applicable to a machine-learning apparatus, a pump-performance prediction apparatus, an inference apparatus, a pump-shape designing apparatus, a machine-learning method, a pump-performance prediction method, an inference method, a pump-shape designing method, a machine learning program, a pump-performance prediction program, an inference program, and a pump-shape designing program.

### REFERENCE SIGNS LIST

1 . . . pump designing system
2 . . . pump
3 . . . machine-learning apparatus
4 . . . pump-shape designing apparatus
5 . . . design database device
6 . . . . CFD analysis apparatus
7 . . . designer terminal apparatus
8 . . . network
10, 10A, 10b . . . learning model
11, 11A, 11b . . . learning data
12 . . . required specifications
13 . . . design information
14 . . . selection-candidate input screen
20 . . . impeller
21 . . . guide vane
22 . . . fluid passage section
23 . . . casing
24 . . . drive machine
25 . . . rotation axis
30 . . . learning-data acquisition section
31 . . . learning-data storage section
32 . . . machine-learning section
33 . . . learned-model storage section
40 . . . required-specification receiving section
41 . . . candidate extracting section
42 . . . learned-model storage section
43 . . . selection receiving section
44 . . . information providing section
50 . . . previously designed data
140 . . . required-specification display field
141 . . . axis display field
142 . . . scatter-diagram display field
143A . . . horizontal axis
143B . . . vertical axis
144 . . . . Pareto front set
145 . . . specification satisfactory candidate
146 . . . selection candidate
147 . . . evaluation-value display field
148 . . . self-organizing map display field
200 . . . blade
200a . . . leading edge
200b . . . trailing edge
200c . . . tip-side edge
200d . . . hub-side edge
200e . . . pressure surface
200f . . . suction pressure surface
201 . . . hub
210a . . . leading edge
210b . . . trailing edge
210c . . . shroud edge
210d . . . hub edge
900 . . . computer

What is claimed is:

1. A machine-learning apparatus comprising:
a learning-data storage section that stores plural sets of learning data including input data and output data, the input data including shape parameters of a pump section having an impeller and a flow passage section in which the impeller is accommodated, the output data including pump performance of a pump having the pump section defined by the shape parameters;
a machine-learning section configured to cause a learning model to learn a correlation between the input data and the output data by inputting the plural sets of the learning data to the learning model; and
a learned-model storage section configured to store the learning model that has been caused to learn the correlation by the machine-learning section.

2. The machine-learning apparatus according to claim 1, wherein the shape parameters of the input data include a meridional shape parameter of the pump section and a 3D blade surface shape parameter of the pump section.

3. The machine-learning apparatus according to claim 2, wherein
the meridional shape parameter of the input data includes at least a maximum diameter of the impeller and an inner diameter of a stationary flow-passage section of the flow passage section, the stationary flow-passage section being located at a discharge side of the impeller, and
the 3D blade surface shape parameter includes at least an average angular momentum of a fluid at a trailing edge of the impeller.

4. The machine-learning apparatus according to claim 1, wherein the output data includes the pump performance represented by at least one of performance parameters including:
point data based on a relationship between flow rate and head;
performance curve data based on the relationship between the flow rate and the head;
point data of a gradient of a performance curve based on the relationship between the flow rate and the head;
point data based on a relationship between the flow rate and shaft power;
performance curve data based on the relationship between the flow rate and the shaft power;
point data based on a relationship between the flow rate and NPSH required;
performance curve data based on the relationship between the flow rate and the NPSH required;
point data based on a relationship between the flow rate and efficiency;
performance curve data based on the relationship between the flow rate and the efficiency;
maximum head ratio; and
maximum shaft-power ratio.

5. A pump-performance prediction apparatus for predicting pump performance of a pump having a pump section using a learning model generated by the machine-learning apparatus according to claim 1, the pump section including an impeller and a flow passage section in which the impeller is accommodated, the pump-performance prediction apparatus comprising:
an input-data acquisition section configured to obtain input data including shape parameters of the pump section; and
an inference section configured to input the input data obtained by the input-data acquisition section into the learning model and infer the pump performance of the pump having the pump section defined by the shape parameters.

6. An inference apparatus comprising:
a memory; and
a processor configured to perform:
an input-data acquisition process of obtaining input data including shape parameters of a pump section that includes an impeller and a flow passage section in which the impeller is accommodated; and
an inference process of inferring pump performance of a pump having the pump section defined by the shape parameters when the input data is obtained in the input data acquisition process.

7. A pump-shape designing apparatus for designing a shape of a pump section using a learning model generated by the machine-learning apparatus according to claim 1, the pump section including an impeller and a flow passage section in which the impeller is accommodated, the pump-shape designing apparatus comprising:
a required-specification receiving section configured to receive required specifications for a pump performance of a pump;
a candidate extracting section configured to extract candidates as specification satisfactory candidates from among multiple candidates for a plurality of pump sections defined by different shape parameters of the plurality of pump sections, the candidates as the specification satisfactory candidates being candidates corresponding to pump performances which are inferred by inputting the shape parameters into the learning model for each candidate and satisfy the required specifications;
a selection receiving section configured to receive a candidate as a selection candidate selected from the specification satisfactory candidates; and
an information providing section configured to provide design information including the shape parameters defining the pump section of the selection candidate and the pump performance of the pump having the pump section corresponding to the selection candidate.

8. The pump-shape designing apparatus according to claim 7, wherein the pump performance includes at least one performance index,
the information providing section is configured to provide visualized information including the performance index visualized for each of the specification satisfactory candidates,
the selection receiving section is configured to receive the candidate as the selection candidate selected on a screen based on the visualized information.

9. The pump-shape designing apparatus according to claim 8, wherein the information providing section is configured to provide the visualized information including one of:
numerical-value information that numerically expresses one performance index for the specification satisfactory candidates;
scatter-diagram information that expresses two or three performance indexes for the specification satisfactory candidates in a scatter diagram; and
self-organizing map information that expresses four or more performance indexes for the specification satisfactory candidates in a self-organizing map,
the selection receiving section is configured to receive the candidate as the selected candidate selected on any one of:
a numerical-value screen based on the numerical-value information;
a scatter-diagram screen based on the scatter-diagram information; and
a self-organizing map screen based on the self-organizing map information.

10. A machine-learning method comprising:
a learning-data storing process of storing plural sets of learning data including input data and output data, the input data including shape parameters of a pump section having an impeller and a flow passage section in which the impeller is accommodated, the output data including pump performance of a pump having the pump section defined by the shape parameters;
a machine-learning process of causing a learning model to learn a correlation between the input data and the output data by inputting the plural sets of the learning data to the learning model; and
a learned-model storing process of storing, in a learned-model storage section, the learning model that has been caused to learn the correlation by the machine-learning process.

11. A machine learning program for causing a computer to execute each process of the machine-learning method according to claim 10.

12. A pump-performance prediction method of predicting pump performance of a pump having a pump section using a learning model generated by the machine-learning method according to claim 10, the pump section including an impeller and a flow passage section in which the impeller is accommodated, the pump-performance prediction method comprising:
an input-data acquisition process of obtaining input data including shape parameters of the pump section; and
an inference process of inputting the input data obtained by the input-data acquisition process into the learning model and inferring the pump performance of the pump having the pump section defined by the shape parameters.

13. A pump-performance prediction program for causing a computer to perform each process of the pump-performance prediction method according to claim 12.

14. An inference method comprising:
a memory; and
a processor configured to perform:
an input-data acquisition process of obtaining input data including shape parameters of a pump section that includes an impeller and a flow passage section in which the impeller is accommodated; and
an inference process of inferring pump performance of a pump having the pump section defined by the shape parameters when the input data is obtained in the input data acquisition process.

15. An inference program for causing a computer to perform each process of the inference method according to claim 14.

16. A pump-shape designing method of designing a shape of a pump section using a learning model generated by the machine-learning method according to claim 10, the pump section including an impeller and a flow passage section in which the impeller is accommodated, the pump-shape designing method comprising:
a required-specification receiving process of receiving required specifications for a pump performance of a pump;
a candidate extracting process of extracting candidates as specification satisfactory candidates from among multiple candidates for a plurality of pump sections defined by different shape parameters of the plurality of pump sections, the candidates as the specification satisfactory candidates being candidates corresponding to pump performances which are inferred by inputting the shape parameters into the learning model for each candidate and satisfy the required specifications;
a selection receiving process of receiving a candidate as a selection candidate selected from the specification satisfactory candidates; and
an information providing process of providing design information including the shape parameters defining the pump section of the selection candidate and the pump performance of the pump having the pump section corresponding to the selection candidate.

17. A pump-shape designing program for causing a computer to perform each process of the pump-shape designing method according to claim 16.
